(19) United States
(12) Patent Application Publication
(10) Pub. No.: US 2024/0213048 A1
(43) Pub. Date: Jun. 27, 2024

(54) SUBSTRATE PROCESSING APPARATUS

(71) Applicant: SEMES CO., LTD., Cheonan-si (KR)

(72) Inventors: Jongwha Kang, Cheonan-si (KR); Sunwook Jung, Hwaseong-si (KR); Wooram Lee, Seoul (KR); Byoungdoo Choi, Cheonan-si (KR); Arah Cho, Daejeon-si (KR); Dongwoon Park, Seoul (KR)

(73) Assignee: SEMES CO., LTD., Cheonan-si (KR)

(21) Appl. No.: 18/391,661

(22) Filed: Dec. 21, 2023

(30) Foreign Application Priority Data
Dec. 26, 2022 (KR) 10-2022-0185009
Feb. 6, 2023 (KR) 10-2023-0015730

(51) Int. Cl. H01L 21/67; H01L 21/677

(52) U.S. Cl. CPC H01L 21/67051; H01L 21/6719; H01L 21/67225; H01L 21/67742

(57) ABSTRACT

A substrate processing apparatus includes a processing unit including a processing vessel with an internal space and a support unit configured to support a substrate and rotate the substrate in a first rotation direction in the internal space, and an exhaust unit configured to exhaust a gas from the internal space, wherein the exhaust unit includes an exhaust pipe providing an exhaust path for the gas exhausted from the internal space, and one or more connectors connecting the processing vessel to the exhaust pipe, and one end of the exhaust pipe is closed, and an open outlet is formed at a remaining end of the exhaust pipe to discharge the gas.

### CROSS-REFERENCE TO RELATED APPLICATION

This application is based on and claims priority under 35 U.S.C. § 119 to Korean Patent Application Nos. 10-2022-0185009, filed on Dec. 26, 2022, and 10-2023-0015730, filed on Feb. 6, 2023, in the Korean Intellectual Property Office, the disclosures of which are incorporated by reference herein in their entireties.

### BACKGROUND

### 1. Field

The technical spirit of the disclosure relates to a substrate processing apparatus. In detail, it relates to a substrate processing apparatus including an exhaust unit.

### 2. Description of the Related Art

To manufacture semiconductor devices, various processes such as cleaning, deposition, photography, etching, and ion implantation are performed. Among these processes, the photography process includes a coating process in which a photosensitive liquid such as a photoresist is coated on a surface of a substrate to form a film, an exposure process in which a circuit pattern is transferred to the film formed on the substrate, and a developing process in which the film formed on the substrate is selectively removed from the exposed area or an opposite area thereof.

A substrate processing device used in the coating process of forming a film by coating a photosensitive liquid such as a photoresist includes a cup-shaped processing vessel having a processing space, a support unit supporting and rotating a substrate W in the processing space, and a nozzle supplying a photoresist onto the substrate W placed on the support unit.

An exhaust unit is coupled to a bottom wall of the processing vessel to exhaust air from the atmosphere of the processing space. Generally, an exhaust unit includes an integrated duct connecting a plurality of processing vessels to a plurality of exhaust pipes that are connected thereto, respectively, and a plurality of processing spaces may be exhausted simultaneously through the integrated duct.

### SUMMARY

An object of the technical spirit of the disclosure is to provide a substrate processing apparatus in which a connector of an exhaust unit is inclined upward in the same direction as a rotation direction of a substrate.

Another object of the technical spirit of the disclosure is to provide a substrate processing apparatus in which an exhaust pipe of an exhaust unit is bent in the same direction as a rotation direction of a substrate.

Additional aspects will be set forth in part in the description which follows and, in part, will be apparent from the description, or may be learned by practice of the presented embodiments of the disclosure.

To achieve the above objects, the technical spirit of the disclosure provides a substrate processing apparatus including a processing unit including a processing vessel with an internal space and a support unit configured to support a substrate and rotate the substrate in a first rotation direction in the internal space, and an exhaust unit configured to exhaust a gas from the internal space, wherein the exhaust unit includes an exhaust pipe providing an exhaust path for the gas exhausted from the internal space, and one or more connectors connecting the processing vessel to the exhaust pipe, and one end of the exhaust pipe is closed, and an open outlet is formed at a remaining end of the exhaust pipe to discharge the gas.

The technical spirit of the disclosure provides a substrate processing apparatus including a processing unit including a processing vessel with an internal space and a support unit configured to support a substrate and rotate the substrate in a first rotation direction in the internal space, and an exhaust unit configured to exhaust a gas from the internal space, wherein the exhaust unit includes an exhaust pipe providing an exhaust path for the gas exhausted from the internal space, one or more connectors connecting the processing vessel to the exhaust pipe, and an outlet discharging the gas, and the connectors are each inclined upward at a preset angle in the same direction as the first rotation direction.

The technical spirit of the disclosure provides a substrate processing apparatus including a housing providing a space in which a substrate is processed, a first processing unit including a first processing vessel having a first internal space in the housing, and a first support unit configured to support the substrate in the first internal space and rotate the substrate in one rotation direction of clockwise and counterclockwise directions, a second support unit including a second processing vessel having a second internal space in the housing and a second support unit configured to support the substrate in the second internal space and rotate the substrate in one rotation direction of clockwise and counterclockwise directions, a first exhaust unit and a second exhaust unit configured to exhaust a gas from the first internal space and the second internal space, respectively, and an integrated duct connected to the first exhaust unit and the second exhaust unit and located at one side based on a unit arrangement direction in which the first exhaust unit and the second exhaust unit are arranged, wherein the first exhaust unit includes a first exhaust pipe providing an exhaust path for the gas exhausted from the first internal space and having one closed end and a remaining end at which an open outlet is formed, and one or more first connector connecting the first processing vessel to the first exhaust pipe, and the second exhaust unit includes a second exhaust pipe providing an exhaust path for the gas exhausted from the second internal space and having one closed end and a remaining end at which an open outlet is formed, and one or more second connectors connecting the first processing vessel to the first exhaust pipe.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a substrate processing apparatus according to an embodiment;

FIG. 2 is a cross-sectional view of a substrate processing apparatus showing a coating block or a developing block;

FIG. 3 is a plan view of the substrate processing apparatus of FIG. 1;

FIG. 4 is a diagram of a hand of a transport robot, according to an embodiment;

FIG. 5 is a schematic plan view of a heat processing chamber of FIG. 4, according to an embodiment;

FIG. 6 is a front view of the heat processing chamber of FIG. 5;

FIG. 7 is a cross-sectional view of a liquid processing chamber in which a rotating substrate is liquid-processed by supplying a processing liquid to the rotating substrate, according to an embodiment;

FIG. 8 is a perspective view of an exhaust unit of a substrate processing apparatus according to an embodiment;

FIG. 9 is a schematic plan view of an exhaust unit of a substrate processing apparatus, according to an embodiment;

FIG. 10 is a cross-sectional view taken in a long axis direction of a connector of an exhaust unit, according to an embodiment; and

FIG. 11 is a schematic plan view of an exhaust unit of a substrate processing apparatus, according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the technical spirit will be described in detail with reference to the accompanying drawings. The same reference numerals are used for the same components in the drawings, and repeated descriptions thereof are omitted.

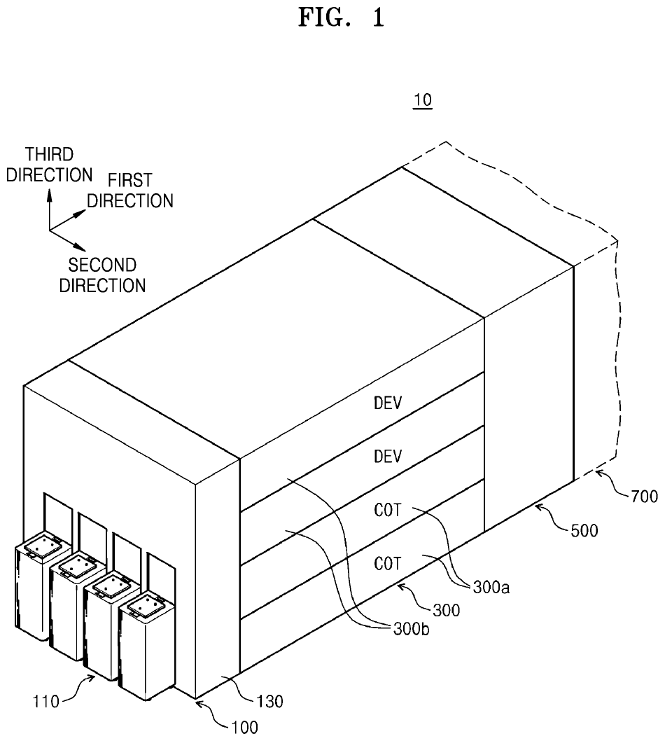

FIG. 1 is a schematic perspective view of a substrate processing apparatus 10 according to an embodiment.

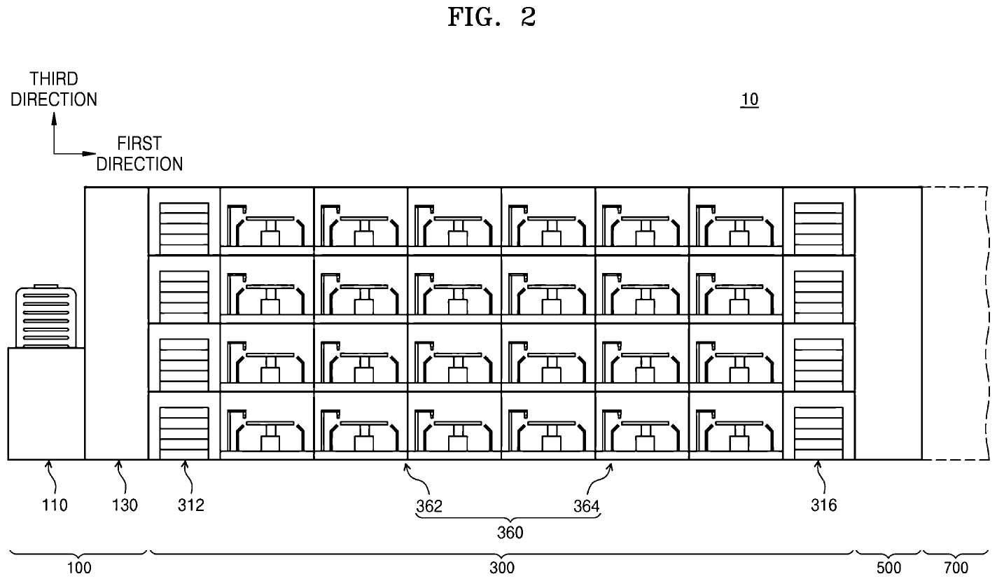

FIG. 2 is a cross-sectional view of the substrate processing apparatus 10 showing a coating block or a developing block of FIG. 1.

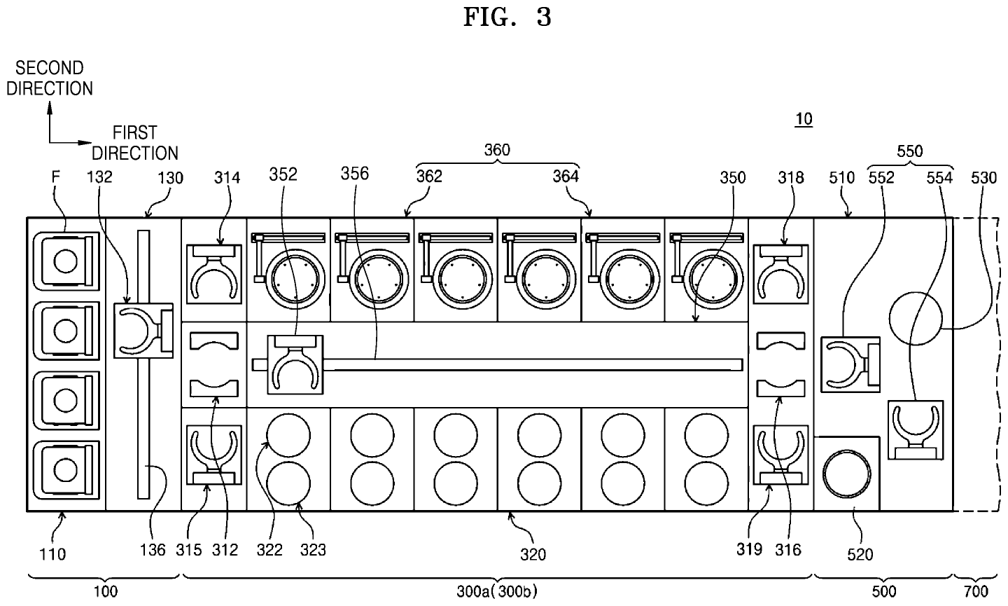

FIG. 3 is a plan view of the substrate processing apparatus 10 of FIG. 1.

Referring to FIGS. 1 to 3, the substrate processing apparatus 10 according to an embodiment may include an index module 100, a processing module 300, and an interface module 500.

According to an embodiment, the index module 100, the processing module 300, and the interface module 500 may be sequentially arranged in a row. Hereinafter, a direction in which the index module 100, the processing module 300, and the interface module 500 are arranged is referred to as a first direction 12, a direction orthogonal to the first direction 12 when viewed from the top is referred to as a second direction 14, and a direction orthogonal to both the first direction 12 and the second direction 14 is defined as a third direction 16.

The index module 100 may transport the substrate W from a container F in which the substrate W is accommodated to the processing module 300, and accommodate the processed substrate W in the container F. A length direction of the index module 100 may be provided as the second direction 14. The index module 100 may include a load port 110 and an index frame 130. Based on the index frame 130, the load port 110 may be located at an opposite side of the processing module 300. The container F in which the substrates W are accommodated may be placed in the load port 110. The load port 110 may be provided in a plural number, and the plurality of load ports 110 may be arranged in the second direction 14.

As the container F, a sealed container F such as a front open unified pod (FOUP) may be used. The container F may be placed in the load port 110 by a transport element such as an overhead transfer, an overhead conveyor, or an automatic guided vehicle, or by an operator.

An index robot 132 may be provided inside the index frame 130. Within the index frame 130, a guide rail 136, a length direction of which is provided as the second direction 14, may be provided. The index robot 132 may be moveably provided on the guide rail 136. The index robot 132 may include a hand on which the substrate W is placed, and the hand may be provided for forward and backward movement, rotation in the third direction 16 as an axis, and movement in the third direction 16.

The processing module 300 may perform a coating process and a developing process on the substrate W. The processing module 300 may receive the substrate W accommodated in the container F and perform a substrate processing process on the substrate W. The processing module 300 may include a coating block 300a and a developing block 300b. The coating block 300a may perform a coating process on the substrate W, and the developing block 300b may perform a developing process on the substrate W.

The coating block 300a may be provided in a plural number and the plurality of coating blocks 300a may be stacked on top of each other. The developing block 300b may be provided in a plural number and the plurality of developing blocks 300b may be stacked on top of each other. According to the embodiment of FIG. 1, two each of the coating block 300a and the developing block 300b may be provided. The coating blocks 300a may be disposed below the developing block 300b. According to an embodiment, the two coating blocks 300a may perform the same process and may be provided with the same structure. The two developing blocks 300b may perform the same process and may be provided with the same structure.

Referring to FIG. 3, the coating block 300a may include a heat processing chamber 320, a transport chamber 350, a liquid processing chamber 360, and buffer chambers 312 and 316. The heat processing chamber 320 may perform a heat processing process on the substrate W. The heat processing process may include a cooling process and a heating process. The liquid processing chamber 360 may supply a liquid on the substrate W to form a liquid film. The liquid film may be a photoresist film or an anti-reflective film. The transport chamber 350 may transport the substrate W between the heat processing chamber 320 and the liquid processing chamber 360 within the coating block 300a.

The transport chamber 350 may have a length direction parallel to the first direction 12. A transport robot 352 may be provided in the transport chamber 350. The transport robot 352 may transport the substrate W between the heat processing chamber 320, the liquid processing chamber 360, and the buffer chambers 312 and 316. According to an embodiment, the transport robot 352 may include a hand on which the substrate W is placed, and the hand may be provided for forward and backward movement, rotation using the third direction 16 as an axis, and movement in the third direction 16. Within the transport chamber 350, a guide rail 356, a length direction of which is parallel to the first direction 12, may be provided, and the transport robot 352 may be moveably provided on the guide rail 356.

The heat processing chamber 320 may be provided in a plural number. The heat processing chambers 320 may be arranged in the first direction 12. The heat processing chambers 320 may be located at one side of the transport chamber 350.

The liquid processing chamber 360 may be provided in a plural number. Some of the liquid processing chambers 360 may be stacked on top of each other. The liquid processing chambers 360 may be located at one side of the transport chamber 350. The liquid processing chambers 360 may be arranged side by side in the first direction 12. Some of the liquid processing chambers 360 may be provided at a position adjacent to the index module 100. Hereinafter, the liquid processing chamber 360 located adjacent to the index module 100 is referred to as a front liquid processing chamber 362. Other some of the liquid processing chambers 360 may be provided adjacent to the interface module 500. Hereinafter, the liquid processing chamber 360 located adjacent to the interface module 500 is referred to as a rear liquid processing chamber 364.

The front liquid processing chamber 362 may coat a first liquid on the substrate W, and the rear liquid processing chamber 364 may coat a second liquid on the substrate W. The first liquid and the second liquid may be different types of liquid. According to an embodiment, the first liquid may be an anti-reflective film, and the second liquid may be a photoresist. The photoresist may be coated on the substrate W on which the anti-reflective film is coated. Optionally, the first liquid may be a photoresist and the second liquid may be an anti-reflective film. In this case, the anti-reflective film may be coated on the substrate W on which a photoresist is coated. Optionally, the first liquid and the second liquid may be the same type of liquid, and may both be photoresists.

The developing block 300b may have the same structure as the coating block 300a, and a liquid processing chamber provided in the developing block 300b may supply a developing solution on the substrate W.

The interface module 500 may connect the processing module 300 to an external exposure device 700. The interface module 500 may include an interface frame 510, an additional process chamber 520, an interface buffer 530, and an interface robot 550.

A fan filter unit that forms a downward airflow therein may be provided at an upper end of the interface frame 510. The additional process chamber 520, the interface buffer 530, and the interface robot 550 may be arranged inside the interface frame 510. The additional process chamber 520 may perform a preset additional process before the substrate W on which the process in the coating block 300a is completely performed may be brought into the exposure device 700. Optionally, the additional process chamber 520 may perform a preset additional process before the substrate W on which the process in the exposure device 700 is completely performed may be brought into the developing block 300b. According to an embodiment, the additional process may be an edge exposure process of exposing an edge area of the substrate W, a top surface cleaning process of cleaning a top surface of the substrate W, or a bottom surface cleaning process of cleaning a bottom surface of the substrate W. The additional process chamber 520 may be provided in a plural number, and the plurality of additional process chamber 520 may be stacked on top of each other. The additional process chambers 520 may all be provided to perform the same process. Optionally, some of the additional process chambers 520 may be provided to perform different processes.

The interface buffer 530 may provide a space in which the substrate W, which is transported between the coating block 300a, the additional process chamber 520, the exposure device 700, and the developing block 300b, temporarily stays during transport. The interface buffer 530 may be provided in a plural number, and the plurality of interface buffers 530 may be stacked on top of each other.

According to an embodiment, based on an extension line in a length direction of the transport chamber 350, the additional process chamber 520 may be placed on one side surface, and the interface buffer 530 may be placed on the other side surface.

The interface robot 550 may transport the substrate W between the coating block 300a, the additional process chamber 520, the exposure device 700, and the developing block 300b. The interface robot 550 may have a transport hand that transports the substrate W. The interface robot 550 may be provided as one or multiple robots. According to an embodiment, the interface robot 550 may include a first robot 552 and a second robot 554. The first robot 552 may transport the substrate W between the coating block 300a, the additional process chamber 520, and the interface buffer 530, the second robot 554 may transport the substrate W between the interface buffer 530 and the exposure device 700, and a second robot 554 may be provided to transport the substrate W between the interface buffer 530 and the developing block 300b.

The first robot 552 and the second robot 554 may each include a transport hand on which the substrate W is placed, and the hand may be provided for forward and backward movement, rotation in a direction parallel to the third direction 16 as an axis, and movement in the third direction 1.

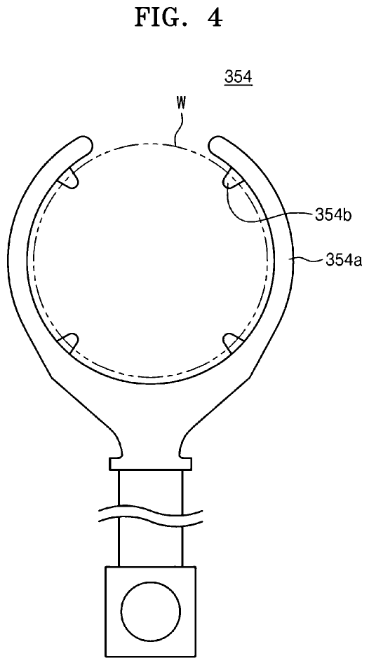

FIG. 4 is a diagram of a hand 354 of a transport robot, according to an embodiment.

Referring to FIG. 4, the hand 354 may include a base 354a and a support protrusion 354b. The base 354a may have an annular ring shape, a circumference of which is partially bent. The base 354a may have an inner diameter larger than a diameter of the substrate W. The support protrusion 354b may extend inward from the base 354a. The support protrusion 354b may be provided in a plural number and the plurality of support protrusions 354b may support an edge area of the substrate W. According to an embodiment, the support protrusions 354b may be provided in four pieces at equal intervals, but are not limited thereto.

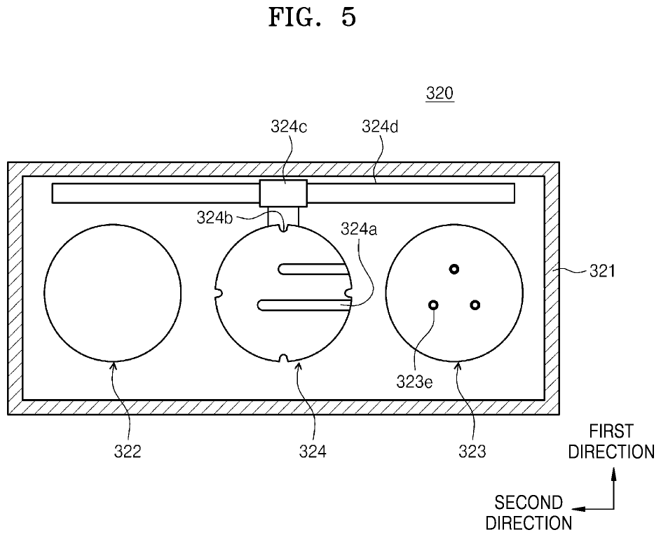

FIG. 5 is a schematic plan view of the heat processing chamber 320 of FIG. 4, according to an embodiment.

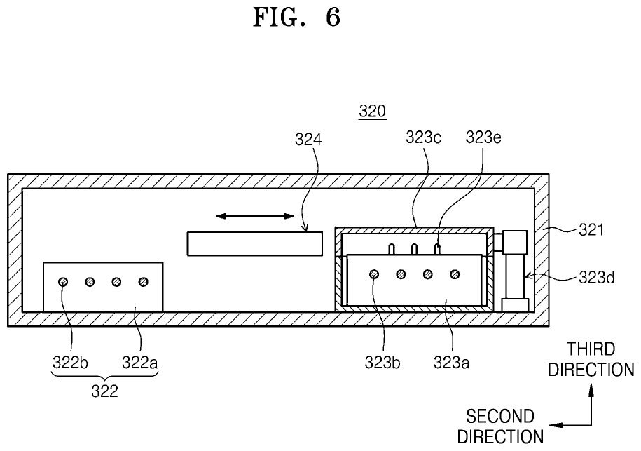

FIG. 6 is a front view of the heat processing chamber 320 of FIG. 5.

Referring to FIGS. 5 and 6, the heat processing chamber 320 may include a housing 321, a cooling unit 322, a heating unit 323, and a transport plate 324. The housing 321 may be provided in a generally rectangular parallelepiped shape. An entrance through which the substrate W enters and exits may be formed in a side wall of the housing 321. The entrance may remain open. A door may be provided to optionally open and close the entrance. The cooling unit 322, the heating unit 323, and the transport plate 324 may be provided within the housing 321. The cooling unit 322 and the heating unit 323 may be arranged in the second direction 14. According to an embodiment, the cooling unit 322 may be located closer to the transport chamber 350 than the heating unit 323.

The cooling unit 322 may include a cooling plate 322a. The cooling plate 322a may have a generally circular shape when viewed from the top. The cooling plate 322a may be provided with a cooling member 322b. According to an embodiment, the cooling member 322b may be formed inside the cooling plate 322a and may serve as a flow path through which a cooling fluid flows.

The heating unit 323 may include a heating plate 323a, a cover 323c, and a heater 323b. The heating plate 323a may have a generally circular shape when viewed from the top. The heating plate 323a may have a larger diameter than the substrate W. The heater 323b may be installed on the heating plate 323a. The heater 323b may be provided as a heating resistor to which current is applied. The heating plate 323a is provided with lift pins 323e that are to be driven up and down in the third direction 16. The lift pin 323e may receive the substrate W from a transport element outside the heating unit 323 and place the substrate W on the heating plate 323a, or may lift the substrate W from the heating plate 323a and transfer the substrate W to the transport element outside the heating unit 323. According to an embodiment, the lift pins 323e may be provided in three pieces. The cover 323c may have a space with an open bottom.

The cover 323c may be disposed above the heating plate 323a and may be moved up and down by a driver 3236d. A space formed by the cover 323c and the heating plate 323a by moving the cover 323c may be provided as a heating space for heating the substrate W.

The transport plate 324 may have a generally disk shape and may have a diameter corresponding to the substrate W. A notch 324b may be formed on an edge of the transport plate 324. The notch 324b may have a shape corresponding to the support protrusion 354b formed on the hand 354 of the transport robot 352 described above. The notch 324b may be provided in a number corresponding to the support protrusion 354b formed on the hand 354, and may be formed at a position corresponding to the support protrusion 354b. When vertical positions of the hand 354 and the transport plate 324 change from a position at which the hand 354 and the transport plate 324 are disposed in a vertical direction, the substrate W is transferred between the hand 354 and the transport plate 324. The transport plate 324 may be mounted on a guide rail 324d and may be moved between a first area 3212 and a second area 3214 along the guide rail 324d by a driver 324c. The transport plate 324 may be provided with a plurality of slit-shaped guide grooves 324a. The guide groove 324a may extend from an end of the transport plate 324 to the inside of the transport plate 324. A length direction of the guide groove 324a may be provided as the second direction 14, and the guide grooves 324a may be spaced apart from each other in the first direction 12. The guide groove 324a may prevent the transport plate 324 and the lift pin 323e from interfering with each other when the substrate W is received and transferred between the transport plate 324 and the heating unit 323.

The substrate W may be cooled while the transport plate 324 on which the substrate W is placed is in contact with the cooling plate 322a. To facilitate heat transfer between the cooling plate 322a and the substrate W, the transport plate 324 may be made of a material with high thermal conductivity. According to an embodiment, the transport plate 324 may be made of metal.

The heating unit 323 provided in some of the heat processing chambers 320 may supply a gas while heating the substrate W to improve an adhesion rate of a photoresist on the substrate W. According to an embodiment, the gas may be a hexamethyldisilane (HMDS) gas.

Hereinafter, a structure of a liquid processing chamber will be described in detail. Below, the liquid processing chamber provided in a coating block is explained as an example. The liquid processing chamber is explained as an example in which a photoresist is coated on the substrate W. However, the liquid processing chamber may be a chamber in which a film such as a protective film or an anti-reflective film is formed on the substrate W. The liquid processing chamber may be a chamber that develops the substrate W by supplying a developing solution to the substrate W.

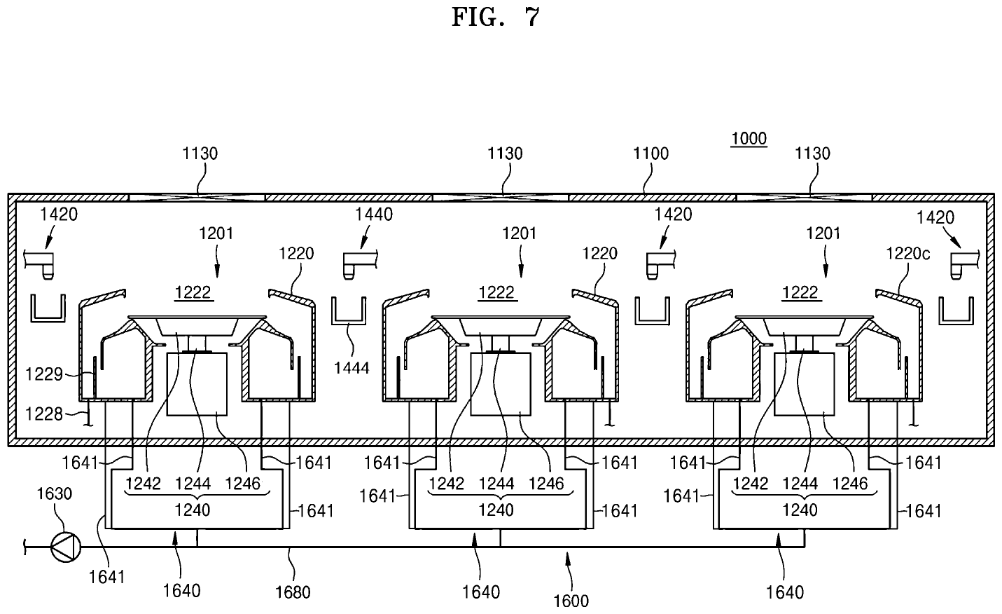

FIG. 7 is a cross-sectional view of a liquid processing chamber 1000 in which the rotating substrate W is liquid-processed by supplying a processing liquid to the rotating substrate W, according to an embodiment.

Referring to FIG. 7, the liquid processing chamber 1000 may include a housing 1100, a processing unit 1201, a liquid supply unit, an exhaust unit 1600, and a controller. The housing 1100 is provided in a shape of a rectangular cylinder with an internal space. An opening may be formed at one side of the housing 1100. The opening may function as a passage through which the substrate W is brought in and out of the housing 1100. A door may be installed in the opening and may open and close the opening.

A fan filter unit 1130 that supplies a downward airflow to an internal space may be placed on an upper wall of the housing 1100. The fan filter unit 1130 may include a fan that introduces outside air into the internal space and a filter that filters outside air. The plurality of fan filter units 1130 may be disposed above a plurality of processing vessels 1220, respectively.

A plurality of processing units 1201 may be provided in the internal space of the housing 1100. The plurality of processing units 1201 may be arranged in one direction. Hereinafter, a direction in which the plurality of processing units 1201 are arranged is referred to as a unit arrangement direction.

The plurality of processing units 1201 may each include the processing vessel 1220 and a support unit 1240. The processing vessel 1220 may have an internal space 1222. An upper portion of the internal space 1222 may be open.

The support unit 1240 may support the substrate W in the internal space 1222 of the processing vessel 1220. The support unit 1240 may rotate the substrate W in the internal space 1222 of the processing vessel 1220. The support unit 1240 may include a support plate 1242, a drive shaft 1244, and a driver 1246. The support plate 1242 may be provided with a circular upper surface. The support plate 1242 may have a smaller diameter than the substrate W. The support plate 1242 is provided to support the substrate W by vacuum pressure. Optionally, the support plate 1242 may have a mechanical clamping structure to support the substrate W. The drive shaft 1244 may be coupled to the center of a bottom surface of the support plate 1242, and the drive shaft 1244 may be provided with the driver 1246 that provides a rotational force to the drive shaft 1244. The driver 1246 may be a motor.

The liquid supply unit may supply a liquid on the substrate W. The liquid supply unit includes a plurality of nozzles 1420 and a processing liquid nozzle 1440. Each nozzle 1420 may supply a liquid to the substrate W provided to each support unit 1240. The plurality of nozzles 1420 may be provided to supply the same type of liquid. According to an embodiment, the nozzle 1420 may supply a rinse solution for cleaning the substrate W. For example, the rinse solution may be water. According to another embodiment, the nozzle 1420 may supply a removal liquid that removes the photoresist from an edge area of the substrate W. For example, the removal liquid may be a thinner. Each of the plurality of nozzles 1420 may be rotated between a process position and a standby position around a rotation axis thereof. The process position is a position at which a liquid is discharged onto the substrate W, and the standby position is a position at which the nozzle 1420 stands by without discharging a liquid onto the substrate W.

The processing liquid nozzle 1440 supplies a processing liquid to the substrate W provided in the support unit 1240. The processing liquid may be a photoresist. The processing liquid nozzle 1440 may be moved between a first process position, a second process position, a third process position, and a standby position along a guide. The first to third process positions may be positions at which a processing liquid is supplied to the substrate W supported on the plurality of support units 1240. The standby position may be a position at which the liquid nozzle 1440 stands by at a standby port 1444 located between the processing units 1201 when a photoresist is not discharged from the processing liquid nozzle 1440.

A gas-liquid separation plate 1229 may be provided in the internal space 1222 of the processing vessel 1220. The gas-liquid separation plate 1229 may be provided extending upward from a bottom wall of the processing vessel 1220. The gas-liquid separation plate 1229 may be provided in a ring shape.

According to an embodiment, the outside of the gas-liquid separation plate 1229 may be provided as a discharge space for discharging a liquid, and the inside of the gas-liquid separation plate 1229 may be provided as an exhaust space for exhausting the atmosphere. A discharge pipe 1228 that discharges a processing liquid may be connected to the bottom wall of the processing vessel 1220. The discharge pipe 1228 may discharge a processing liquid flowing between a side wall of the processing vessel 1220 and the gas-liquid separation plate 1229 to the outside of the processing vessel 1220. An airflow flowing in a space between the side wall of the processing vessel 1220 and the gas-liquid separation plate 1229 may flow into the inside of the gas-liquid separation plate 1229. In this process, a processing liquid contained in the airflow is discharged to the outside of the processing vessel 1220 through the discharge pipe 1228 in the discharge space, and the airflow flows into the exhaust space of the processing vessel 1220. Although not shown, an elevating driver that adjusts relative heights of the support plate 1242 and the processing vessel 1220 may be provided.

A plurality of exhaust units 1640 may be connected to the plurality of processing units 1201, respectively. A plurality of connection units 1641 may each connect the processing unit 1201 to the exhaust unit 1640. Although FIG. 7 shows the case in which four connectors 1641 connect one processing unit 1201 to one exhaust unit 1640, the number of connectors 1641 is not limited thereto and may be designed in various ways as needed.

The plurality of exhaust units 1640 may be arranged in the unit arrangement direction in which the plurality of processing units 1201 are arranged. The plurality of exhaust units 1640 may be connected to an integrated duct 1680. The integrated duct 1680 may be placed at one side based on the unit arrangement direction. When the unit arrangement direction is the X axis, the integrated duct 1680 may be positioned in the Y axis direction based on the unit arrangement direction. A length direction of the integrated duct 1680 may be generally parallel to the unit arrangement direction. The integrated duct 1680 may each be provided with a pressure reducing member 1630 that provides a flow pressure for exhaust. For example, the pressure reducing member 1630 may be a pump or a fan.

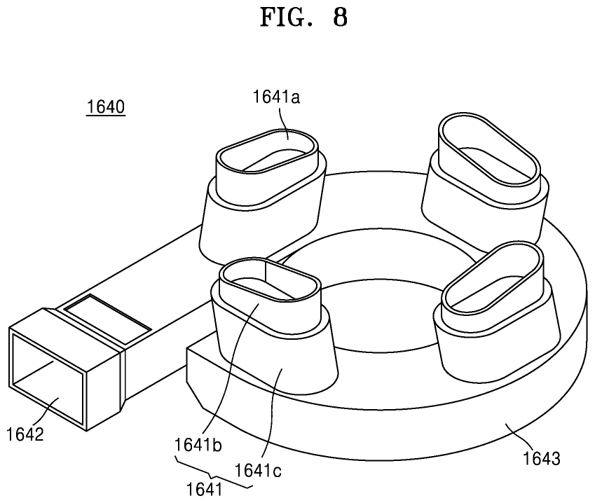

FIG. 8 is a perspective view of an exhaust unit of the substrate processing apparatus 10 according to an embodiment.

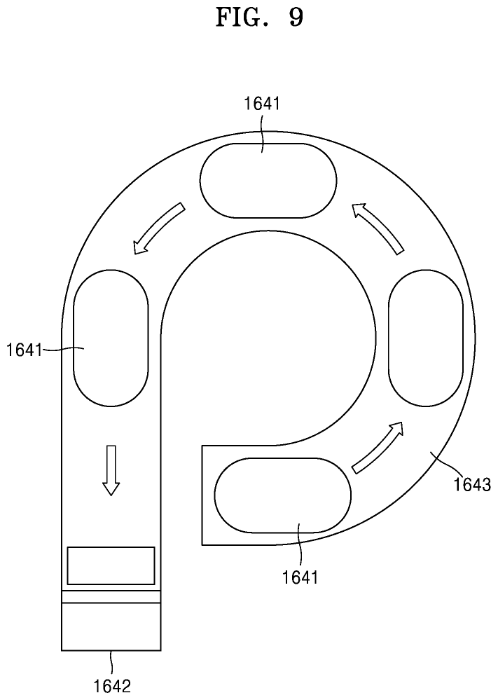

FIG. 9 is a schematic plan view of the exhaust unit 1640 of the substrate processing apparatus 10, according to an embodiment.

Referring to FIGS. 8 and 9, the exhaust unit 1640 of the substrate processing apparatus 10 according to an embodiment may include all or some of the connector 1641, an outlet 1642, and an exhaust pipe 1643.

The exhaust pipe 1643 may provide an exhaust path for gas exhausted from the internal space 1222. The exhaust pipe 1643 may be bent in the same direction as a rotation direction of the support unit 1240. The exhaust pipe 1643 may be curved but may be formed as one piece. In this case, the rotation direction of the support unit 1240 may be a direction in which the substrate W is rotated and may be clockwise or counterclockwise.

For example, as shown in FIG. 9, when the support unit 1240 rotates the substrate W counterclockwise, the exhaust pipe 1643 may be bent counterclockwise. One end of the exhaust pipe 1643 may be closed, and the outlet 1642 may be formed at the other end of the exhaust pipe 1643. The exhaust pipe 1643 may be bent counterclockwise from one end to the other end and may be formed as one piece. Accordingly, the exhaust unit 1640 according to the disclosure may guide a flow of an exhaust airflow in one direction. That is, the flow of exhaust airflow may be guided only in the same direction as the rotation direction of the support unit 1240. In this case, the closed end of the exhaust pipe 1643 and the other end at which the outlet 1642 is formed may be formed at positions in a clockwise or counterclockwise direction to be the same as the rotation direction of the support unit 1240.

The connector 1641 may connect the housing 1100 to the exhaust pipe 1643. The exhaust unit 1640 according to the disclosure may include one or more connectors 1641. FIGS. 8 and 9 show four connectors 1641, but the connectors 1641 are not limited thereto and may be designed in various ways as needed. The plurality of connectors 1641 may be placed at equal intervals from each other. For example, when the exhaust unit 1640 includes the four connectors 1641, each of the connectors 1641 may be placed about 90° apart from the neighboring connector 1641. The plurality of connectors 1641 may be arranged at equal intervals from one end to the other end of the exhaust pipe 1643.

The connector 1641 may be formed to be inclined in the same direction as the rotation direction of the support unit 1240. The connector 1641 may be inclined upward at a preset angle in the same direction as the rotation direction of the support unit 1240. For example, as shown in FIG. 8, the connector 1641 may be inclined upward in a counterclockwise direction. In this case, the preset angle may be about 0° to about 90°. The preset angles of the plurality of connectors 1641 may be the same, but are not limited thereto, and the plurality of connectors 1641 may be inclined at different angles.

In the case of a Y-shaped exhaust unit according to a comparative example, there is a section in which a direction of an airflow generated along with rotation of the support unit and an exhaust direction do not match each other. In at least a portion of the exhaust unit, airflow irregularities occur, and for example, a vortex occurs in a section against a direction of an exhaust airflow. Therefore, there is a limit in improving exhaust performance.

The connectors 1641 may include an upper end portion 1641b inserted into and coupled to the housing 1100, and a lower end portion 1641c connecting the upper end portion 1641b to the exhaust pipe 1643. A cross-sectional area of the lower end portion 1641c may be larger than a cross-sectional area of the upper end portion 1641b. However, without being limited thereto, cross-sectional areas of the lower end portion 1641c and the upper end portion 1641b may be the same, or a cross-sectional area of the lower end portion 1641c may be smaller than a cross-sectional area of the upper end portion 1641b. An exhaust port 1641a through which a gas flows may be formed at one end of the upper end portion 1641b inserted into the housing 1100.

A cross section of the exhaust port 1641a may have an oval shape. The cross section of the exhaust port 1641a may have an oval shape with a long axis in a rotation direction of the support unit 1240. The exhaust port 1641a may be installed in the exhaust pipe 1643, and a cross section of the exhaust port 1641a may have an oval shape with a long axis in a direction parallel to a virtual tangent of the exhaust pipe 1643.

The upper end portions 1641b of the plurality of connectors 1641 may have different cross-sectional areas. However, without being limited thereto, the upper end portions 1641b of the plurality of connectors 1641 may also be the same.

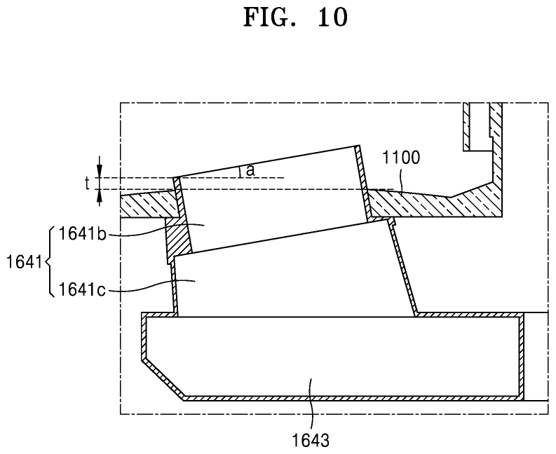

FIG. 10 is a cross-sectional view taken in a long axis direction of a connector of an exhaust unit, according to an embodiment.

Referring to FIG. 10, at least a portion of the upper end portion 1641b of the connectors 1641 may be inserted into and coupled to the housing 1100. In this case, the upper end portion 1641b may be coupled to the housing 1100 to be higher than a bottom surface of the housing 1100 by a preset height t. The upper end portion 1641b may be coupled to the housing 1100 to be higher than the bottom surface of the housing 1100 by the preset height t, and thus a gas and a liquid may be separated from each other. For example, chemicals such as a photoresist may be prevented from flowing into the exhaust unit 1640.

The connectors 1641 may be formed to be inclined in the same direction as the rotation direction of the support unit 1240. The connectors 1641 may be inclined upward at a preset angle ‘a’ in the same direction as the rotation direction of the support unit 1240. In this case, the preset angle may be about 0° to about 90°.

In the exhaust unit 1640 according to an embodiment, the connectors 1641 may be inclined upward at a preset angle in the same direction as the rotation direction of the support unit 1240, and thus a direction of an airflow and a direction of exhaust may be consistent in all sections. Due to the angle of the connectors 1641, stagnation of a rotating air current may be suppressed. Therefore, airflow irregularities may be resolved and exhaust performance may be improved.

According to the disclosure, accumulation of fume may be reduced at a position at which a vortex occurs. In addition, by improving exhaust performance, process performance may be improved, and for example, a product maintenance period may be increased and a constant thickness of a photoresist may be maintained.

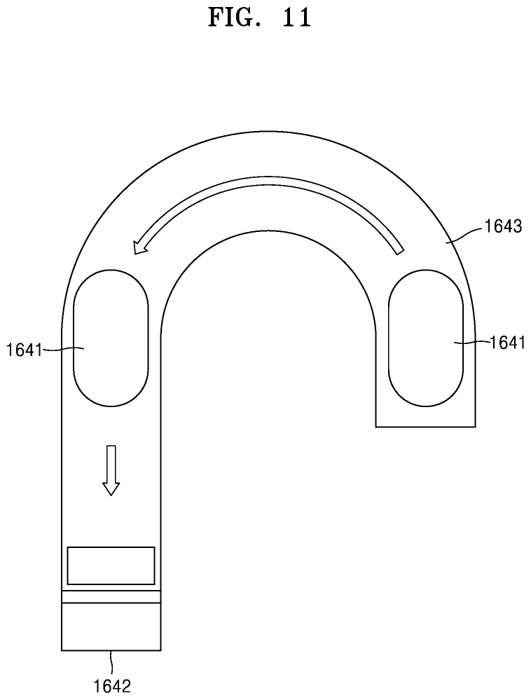

FIG. 11 is a schematic plan view of the exhaust unit 1640 of a substrate processing apparatus, according to another embodiment.

Referring to FIG. 11, the exhaust unit 1640 according to another embodiment may include one or more connectors 1641. Two connectors 1641 may be located in the exhaust pipe 1643. The plurality of connectors 1641 may be placed at equal intervals from each other. For example, when the exhaust unit 1640 includes the two connectors 1641, each of the connectors 1641 may be arranged at an interval of about 180° from the neighboring connector 1641. The plurality of connectors 1641 may be arranged at equal intervals from the closed end of the exhaust pipe 1643 to the other end at which the outlet 1642 is formed.

As above, embodiments have been disclosed in the drawings and specification. In this specification, embodiments have been described using particular terms, but this is only used for the purpose of explaining the technical spirit of the disclosure and is not used to limit the meaning or scope of the disclosure described in the claims. Therefore, those skilled in the art will understand that various modifications and other equivalent embodiments are possible therefrom. Therefore, the true technical scope of the disclosure needs to be determined by the technical spirit of the attached claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a processing unit including a processing vessel with an internal space and a support unit configured to support a substrate and rotate the substrate in a first rotation direction in the internal space; and
an exhaust unit configured to exhaust a gas from the internal space,
wherein the exhaust unit includes:
an exhaust pipe providing an exhaust path for the gas exhausted from the internal space; and
one or more connectors connecting the processing vessel to the exhaust pipe; and
wherein one end of the exhaust pipe is closed, and an open outlet is formed at a remaining end of the exhaust pipe to discharge the gas.

2. The substrate processing apparatus of claim 1, wherein the connectors are each inclined upward at a preset angle in a same direction as the first rotation direction.

3. The substrate processing apparatus of claim 1,
wherein each of the connectors
includes an upper end portion and a lower end portion, wherein the upper end portion is coupled to the processing vessel and
includes an exhaust port through which the gas flows and the lower end portion connects the upper end portion to the exhaust pipe.

4. The substrate processing apparatus of claim 3, wherein cross-sectional areas of the upper end portions are different from each other.

5. The substrate processing apparatus of claim 3, wherein the upper end portion is coupled to the processing vessel to be higher than a bottom surface of the processing vessel by a preset height.

6. The substrate processing apparatus of claim 3, wherein a cross-sectional area of the lower end portion is larger than a cross-sectional area of the upper end portion.

7. The substrate processing apparatus of claim 3, wherein a cross section of the exhaust port has an oval shape with a long axis in the first rotation direction.

8. The substrate processing apparatus of claim 2, wherein the preset angle is about 0° to about 90°.

9. The substrate processing apparatus of claim 1, wherein the one or more connectors are arranged at equal intervals.

10. The substrate processing apparatus of claim 1, wherein the exhaust pipe has an integrated shape bent in a same direction as the first rotation direction.

11. The substrate processing apparatus of claim 1, wherein the first rotation direction is one of clockwise and counterclockwise directions.

12. A substrate processing apparatus comprising:
a processing unit including a processing vessel with an internal space and a support unit configured to support a substrate and rotate the substrate in a first rotation direction in the internal space; and
an exhaust unit configured to exhaust a gas from the internal space,
wherein the exhaust unit includes:
an exhaust pipe providing an exhaust path for the gas exhausted from the internal space;
one or more connectors connecting the processing vessel to the exhaust pipe; and
an outlet discharging the gas; and
wherein the connectors are each inclined upward at a preset angle in a same direction as the first rotation direction.

13. The substrate processing apparatus of claim 12, wherein the preset angle is about 0° to about 90°.

14. The substrate processing apparatus of claim 12, wherein the one or more connectors are arranged at equal intervals.

15. The substrate processing apparatus of claim 12, wherein the exhaust pipe has an integrated shape bent in a same direction as the first rotation direction.

16. The substrate processing apparatus of claim 12, wherein the first rotation direction is one of clockwise and counterclockwise directions.

17. The substrate processing apparatus of claim 12, wherein the exhaust pipe has one closed end and a remaining end at which the outlet is formed.

18. A substrate processing apparatus comprising:
a housing providing a space in which a substrate is processed;
a first processing unit including a first processing vessel having a first internal space in the housing, and a first support unit configured to support the substrate in the first internal space and rotate the substrate in one rotation direction of clockwise and counterclockwise directions;
a second support unit including a second processing vessel having a second internal space in the housing and a second support unit configured to support the substrate in the second internal space and rotate the substrate in one rotation direction of clockwise and counterclockwise directions;
a first exhaust unit and a second exhaust unit configured to exhaust a gas from the first internal space and the second internal space, respectively; and
an integrated duct connected to the first exhaust unit and the second exhaust unit and located at one side based on a unit arrangement direction in which the first exhaust unit and the second exhaust unit are arranged,
wherein the first exhaust unit includes:
a first exhaust pipe providing an exhaust path for the gas exhausted from the first internal space and having one closed end and a remaining end at which an open outlet is formed; and
one or more first connector connecting the first processing vessel to the first exhaust pipe; and
wherein the second exhaust unit includes:
a second exhaust pipe providing an exhaust path for the gas exhausted from the second internal space and having one closed end and a remaining end at which an open outlet is formed; and
one or more second connectors connecting the first processing vessel to the first exhaust pipe.

19. The substrate processing apparatus of claim 18, wherein the first connector and the second connector are each inclined upward at a preset angle in the same direction as the rotation direction.

20. The substrate processing apparatus of claim 18, wherein the exhaust pipe has an integrated shape bent in the same direction as the rotation direction.
